(19) United States
(12) Patent Application Publication
(10) Pub. No.: US 2009/0004426 A1
(43) Pub. Date: Jan. 1, 2009

(54) Suppression of Oxygen Precipitation in Heavily Doped Single Crystal Silicon Substrates

(75) Inventors: Robert J. Falster, London (GB); Luca Moiraghi, Milano (IT); DongMyun Lee, Saint Charles, MO (US); Chanrae Cho, Austin, TX (US); Marco Ravani, Novara (IT)

Correspondence Address: Richard A. Schuth (MEMC);Armstrong Teasdale LLP, One Metropolitan Square, Suite 2600, St. Louis, MO, 63102-2740, US

(73) Assignee: MEMC Electronic Materials, Inc., St. Peters, MO (US)

(21) Appl. No.: 11/771,667

(22) Filed: Jun. 29, 2007

(51) Int. Cl. B32B 3/02; C30B 33/06

(52) U.S. Cl. 428/64.1; 117/1

(57) ABSTRACT

This invention generally relates to a process for suppressing oxygen precipitation in epitaxial silicon wafers having a heavily doped silicon substrate and a lightly N-doped silicon epitaxial layer by dissolving existing oxygen clusters and precipitates within the substrate. Furthermore, the formation of oxygen precipitates is prevented upon subsequent oxygen precipitation heat treatment.

### BACKGROUND OF THE INVENTION

The present invention generally relates to epitaxial semiconductor structures, especially epitaxial silicon wafers used in the manufacture of electronic components, and to methods for their preparation. More specifically, the epitaxial structures comprise a single crystal silicon substrate that is heavily doped with an N-type dopant (N+) or a P-type dopant (P+) and an epitaxial layer which is lightly doped with an N-type dopant (N−), wherein oxygen precipitation is suppressed in the substrate.

Single crystal silicon, the starting material for most processes for the fabrication of semiconductor electronic components, is commonly prepared by the Czochralski process, wherein a single seed crystal is immersed into molten silicon and then grown by extraction. As molten silicon is contained in a quartz crucible, it is contaminated with various impurities, among which is mainly oxygen. As such, oxygen is present in supersaturated concentrations in the wafers sliced from single crystal silicon grown by this method.

During the thermal treatment cycles typically employed in the fabrication of electronic devices, oxygen precipitate nucleation centers may form and ultimately grow into large oxygen clusters or precipitates. Depending upon their location, such precipitates can be beneficial or detrimental. When present in active device regions of the wafer, they can impair the operation of the device. When present outside these regions, oxygen precipitates may serve as a gettering site for metals.

Various approaches have been used to manage oxygen precipitation behavior in wafers. For example, in U.S. Pat. No. 5,994,761, Falster et al. disclose a process for installing a non-uniform concentration of vacancies in a wafer in a rapid thermal annealer whereby in a subsequent oxygen precipitation heat-treatment, oxygen precipitates form in the vacancy-rich regions but not in the vacancy-lean regions. In U.S. Pat. No. 6,336,968, Falster discloses a process in which non-oxygen precipitating wafers are prepared by rapid thermally annealing the wafers in an oxygen-containing atmosphere or by slow-cooling the wafers through the temperature range at which vacancies are relatively mobile.

While these techniques have proven useful, to-date, for typical silicon wafers, epitaxial wafer structures comprising heavily doped substrates present somewhat different challenges. For example, uncontrolled oxygen precipitation in heavily doped substrates can lead to the generation of relatively large concentrations of silicon self-interstitials at high temperatures because of their emission during oxygen precipitate growth. Relatively large concentrations of silicon self-interstitials, in turn, tend to promote diffusion of dopant (or other impurities) from the heavily doped substrate into the more lightly doped, N− device layer, thereby potentially altering critical characteristics, such as avalanche breakdown voltage, in some power devices.

### SUMMARY OF THE INVENTION

Among the various aspects of the present invention is a process for controlling oxygen precipitation behavior in epitaxial silicon structures with heavily doped substrates and the resulting structures, per se.

Briefly, therefore, one aspect of the present invention is an epitaxial silicon wafer comprising a heavily doped silicon substrate that has a resistivity of less than about 5 mΩ*cm and is substantially free from oxygen precipitate nuclei. The wafer also comprises an N− silicon epitaxial layer having a resistivity of greater than about 100 mΩ*cm.

Other objects and features of this invention will be in part apparent and in part pointed out hereinafter.

### DETAILED DESCRIPTION OF THE PREFERRED EMBODIMENTS

In accordance with one aspect of the present invention, N−/N+ or N−/P+ epitaxial silicon wafers may be prepared with improved oxygen precipitation behavior and, as a result, a greater degree of control over diffusion of dopant (and other impurities) from the heavily doped substrate into the more lightly doped, N− epitaxial layer. In one embodiment, the resulting epitaxial wafers will not form oxygen precipitates during a subsequent oxygen precipitation heat treatment (e.g., annealing the wafer at a temperature of 800° C. for four hours and then at a temperature of 1000° C. for sixteen hours).

### I. Silicon Substrate

The starting material for the process of the present invention is a single crystal silicon wafer that has been sliced from a single crystal ingot grown in accordance with Czochralski crystal growing methods. The single crystal silicon wafer has a central axis; a front surface and a back surface that are generally perpendicular to the central axis; a circumferential edge; and a radius extending from the central axis to the circumferential edge. The wafer may be polished or, alternatively, it may be lapped and etched, but not polished. In addition, the wafer may have vacancy or self-interstitial point defects as the predominant intrinsic point defect. For example, the wafer may be vacancy dominated from center to edge, self-interstitial dominated from center to edge, or it may contain a central core of vacancy dominated material surrounded by an axially symmetric ring of self-interstitial dominated material.

Czochralski-grown silicon typically has an oxygen concentration within the range of about 5×10¹⁷ to about 9×10¹⁷ atoms/cm³ (ASTM standard F-121-83). Because the oxygen precipitation behavior of the wafer is essentially erased by the present process (i.e., the wafer is essentially rendered non-oxygen precipitating, even if subjected to an oxygen precipitation heat treatment), the starting heavily doped wafer may have an oxygen concentration falling anywhere within or even outside the range typically attainable by the Czochralski process.

Depending on the cooling rate of the single crystal silicon ingot from the melting point of silicon (about 1410° C.) through the range of about 750° C. to about 350° C., oxygen precipitate nucleation centers may form in the single crystal silicon ingot from which the heavily doped wafer is sliced. The presence or absence of these nucleation centers in the starting material is not critical to the present invention. Preferably, however, these centers are capable of being dissolved by the rapid thermal anneal heat-treatment of the present invention.

The silicon wafer is heavily doped wafer with one or more N-type or P-type dopants. Typical N-type dopants include phosphorous and arsenic. In one embodiment, the dopant is phosphorous. In another embodiment, the dopant is arsenic. In yet another embodiment, phosphorous and arsenic are both used as dopants. Typical P-type dopants include boron, aluminum, and gallium. In one embodiment, the dopant is boron. In another embodiment, the dopant is aluminum, while in another embodiment, the dopant is gallium. In yet another embodiment, any combination of boron, aluminum, and gallium is used as the dopant. Regardless of the dopant(s), the total concentration of dopant(s) is such that the wafer has a resistivity of less than about 5 mΩ·cm, such wafers typically being referred to as N+ or P+ wafers. In one embodiment, the dopant concentration is sufficient to provide the wafer with a resistivity of less than about 3 mΩ·cm. In certain embodiments, resistivities of less than about 2 mΩ·cm will be preferred. In one preferred embodiment, the dopant concentration is sufficient to provide the wafer with a resistivity of less than about 1 mΩ·cm.

The resistivity values noted above correspond to an N-type dopant concentration that may be greater than about 1.24×10¹⁹ at/cm³. For example, the heavily doped wafer has N-type dopant(s) present in a concentration greater than about 2.25×10¹⁹ at/cm³, such as greater than about 3.43×10¹⁹ at/cm³. In one preferred embodiment, the heavily doped wafer has N-type dopant(s) present in a concentration greater than about 7.36×10¹⁹ at/cm³. Similarly, the resistivity values noted above correspond to a P-type dopant concentration that may be greater than about 2.1×10¹⁹ at/cm³. For example, the heavily doped wafer has P-type dopant(s) present in a concentration greater than about 3.7×10¹⁹ at/cm³, such as greater than about 5.7×10¹⁹ at/cm³. In one preferred embodiment, the heavily doped wafer has P-type dopant(s) present in a concentration greater than about 1.2×10²⁰ at/cm³.

### II. Annealing Step

The heavily doped wafer is subjected to a heat treatment step to cause dissolution of any pre-existing oxygen clusters and any pre-existing oxidation induced stacking faults (OISF) nuclei. Preferably, this heat treatment step is carried out in a rapid thermal annealer (RTA) in which the wafer is rapidly heated to a target temperature, then annealed at that temperature for a relatively short period of time. In general, the wafer is rapidly heated to a temperature in excess of 1150° C., preferably at least 1175° C., typically at least about 1200° C., and, in some embodiments, to a temperature of about 1200° C. to 1275° C. The wafer will generally be maintained at this temperature for at least one second, typically for at least several seconds (e.g., at least 3), and potentially for several tens of seconds (such as between about 10 and about 60 seconds, e.g., 20, 30, 40, or 50 seconds) depending upon the concentration, type and size of any pre-existing defects.

The rapid thermal anneal may be carried out in any of a number of commercially available RTA furnaces in which wafers are individually heated by banks of high power lamps. Rapid thermal annealer furnaces are capable of rapidly heating a silicon wafer, e.g., they are capable of heating a wafer from room temperature to 1200° C. in a few seconds. One such commercially available RTA furnace is the 3000 RTP available from Mattson Technology (Freemont, Calif.).

### III. Controlling Vacancy Concentration and Profile

In addition to dissolving a variety of pre-existing oxygen clusters and OISF nuclei, the annealing step will increase the number density of crystal lattice vacancies in the heavily doped wafer. Information obtained to date suggests that certain oxygen-related defects, such as ring OISF, are high temperature nucleated oxygen agglomerates catalyzed by the presence of a high concentration of vacancies. Furthermore, in high vacancy regions, oxygen clustering is believed to occur rapidly at elevated temperatures, as opposed to regions of low vacancy concentration where behavior is more similar to regions in which oxygen precipitate nucleation centers are lacking. Because oxygen precipitation behavior is influenced by vacancy concentration, therefore, the density of vacancies in the heat-treated wafer is controlled in the process of the present invention to limit or even avoid oxygen precipitation in a subsequent oxygen precipitation heat treatment. Advantageously, the (number) density of vacancies in the annealed wafer can be controlled by limiting the cooling rate from the annealing temperature, by including a sufficient partial pressure of oxygen in the annealing atmosphere, or by doing both.

A. Controlling the Cooling Atmosphere

The vacancy concentration in the annealed wafer may be controlled, at least in part, by controlling the atmosphere in which the heat-treatment is carried out. Experimental evidence obtained to date suggests that the presence of a significant amount of oxygen suppresses the vacancy concentration in the annealed wafer. Without being held to any particular theory, it is believed that the rapid thermal annealing treatment in the presence of oxygen results in the oxidation of the silicon surface and, as a result, acts to create an inward flux of silicon self-interstitials. This inward flux of self-interstitials has the effect of gradually altering the vacancy concentration profile by causing Frankel pair recombinations to occur, beginning at the surface and then moving inward.

Regardless of the mechanism, the annealing step is carried out in the presence of an oxygen-containing atmosphere in one embodiment. That is, the anneal is carried out in an atmosphere containing oxygen gas (O₂), water vapor, or an oxygen-containing compound gas which is capable of oxidizing an exposed silicon surface. The atmosphere may thus consist entirely of oxygen or oxygen compound gas, or it may additionally comprise a non-oxidizing gas, such as argon. However, when the atmosphere is not entirely oxygen, the atmosphere will preferably contain a partial pressure of oxygen of at least about 0.001 atmospheres (atm.), or 1,000 parts per million atomic (ppma). More preferably, the partial pressure of oxygen in the atmosphere will be at least about 0.002 atm. (2,000 ppma), still more preferably 0.005 atm. (5,000 ppma), and still more preferably 0.01 atm. (10,000 ppma).

B. Controlling the Cooling Rate

Intrinsic point defects (vacancies and silicon self-interstitials) are capable of diffusing through single crystal silicon with the rate of diffusion being temperature dependent. The concentration profile of intrinsic point defects, therefore, is a function of the diffusivity of the intrinsic point defects and the recombination rate as a function of temperature. For example, the intrinsic point defects are relatively mobile at temperatures in the vicinity of the temperature at which the wafer is annealed in the rapid thermal annealing step, whereas they are essentially immobile for any commercially practical time period below or at temperatures of as much as 700° C. Experimental evidence obtained to-date suggests that the effective diffusion rate of vacancies slows considerably, such that vacancies can be considered to be immobile for any commercially practical time period, at temperatures less than about 700° C. and perhaps less than about 800° C., 900° C., or even 1,000° C.

Accordingly, in one embodiment the concentration of vacancies in the annealed wafer is controlled, at least in part, by controlling the cooling rate of the wafer through the temperature range in which vacancies are relatively mobile. Such control is exercised for a time period sufficient to reduce the number density of crystal lattice vacancies in the cooled wafer prior to cooling the wafer below the temperature range in which vacancies are relatively mobile. As the temperature of the annealed wafer is decreased through this range, the vacancies diffuse to the wafer surface and become annihilated, leading to a change in the vacancy concentration profile. The extent of such change depends on the length of time the annealed wafer is maintained at a temperature within this range and the magnitude of the temperature, with greater temperatures and longer diffusion times generally leading to increased diffusion. In general, the average cooling rate from the annealing temperature to the temperature at which vacancies are practically immobile (e.g., about 950° C.) is preferably no more than 20° C. per second, more preferably no more than about 10° C. per second, and still more preferably no more than about 5° C. per second.

Alternatively, the temperature of the annealed wafer following the high temperature anneal may be reduced quickly (e.g., at a rate greater than about 20° C./second) to a temperature of less than about 1150° C. but greater than about 950° C., and then held for a time period that is dependent upon the holding temperature. For example, several seconds (e.g., at least about 2, 3, 4, 6 or more) may be sufficient for temperatures near 1150° C., whereas several minutes (e.g., at least about 2, 3, 4, 6 or more) may be required for temperatures near 950° C. to sufficiently reduce the vacancy concentration.

Once the annealed wafer is cooled to a temperature outside the range of temperatures at which crystal lattice vacancies are relatively mobile, the cooling rate does not appear to significantly influence the precipitating characteristics of the wafer and, as such, does not appear to be narrowly critical.

Conveniently, the cooling step may be carried out in the same atmosphere in which the heating step is carried out. Suitable atmospheres include, e.g., nitriding atmospheres (i.e., atmospheres containing nitrogen gas (N₂) or a nitrogen-containing compound gas that is capable of nitriding an exposed silicon surface, such as ammonia); oxidizing (oxygen-containing) atmospheres; non-oxidizing, non-nitriding atmospheres (such as argon, helium, neon, carbon dioxide); and combinations thereof.

### IV. Annealed Wafer Oxygen Profile

While the rapid thermal treatments employed herein may result in the out-diffusion of a small amount of oxygen from the surface of the front and back surfaces of the wafer, the resulting annealed wafer has a substantially uniform interstitial oxygen concentration as a function of distance from the silicon surface. For example, the annealed wafer will have a substantially uniform concentration of interstitial oxygen from the center of the wafer to regions of the wafer that are within about 15 microns of the silicon surface, more preferably from the center of the silicon to regions of the wafer that are within about 10 microns of the silicon surface, even more preferably from the center of the silicon to regions of the wafer that are within about 5 microns of the silicon surface, and most preferably from the center of the silicon to regions of the wafer that are within about 3 microns of the silicon surface. In this context, a substantially uniform oxygen concentration shall mean a variance in the oxygen concentration of no more than about 50%, preferably no more than about 20%, and most preferably no more than about 10%.

### V. Epitaxial Growth

An epitaxial layer is deposited or grown on a surface of the annealed silicon wafer to an average thickness of at least about 5 cm by means generally known in the art to form the epitaxial silicon wafer. Typically, epitaxial growth is achieved by chemical vapor deposition, because this is one of the most flexible and cost effective methods for growing epitaxial layers on semiconductor material; see, e.g., U.S. Pat. No. 5,789,309. Doping of the epitaxial layer may take place after or during the growth process. Regardless of the doping method, the resulting epitaxial layer has an N-type dopant concentration to provide the epitaxial layer with a resistivity of at least about 10 mΩ·cm, such as at least about 100 mΩ·cm. For example, the epitaxial layer will typically have a resistivity of between about 100 mΩ·cm and about 100 Ω·cm. In one application, the epitaxial layer will have a resistivity of between about 300 mΩ·cm and about 10 Ω·cm.

As an alternative means of characterizing the N-doped epitaxial layer, the epitaxial layer will typically have a dopant concentration of less than about 4.8×10¹⁸ at/cm, such as between about 4.3×10¹³ at/cm and about 7.8×10¹⁶ at/cm. In one application, the N-type epitaxial layer has a dopant concentration between about 4.4×10¹⁴ at/cm and about 1.9×10¹⁶ at/cm.

The epitaxial layer is doped, as described, with one or more N-type dopants selected, for example, from the group consisting of phosphorous, arsenic, and antimony. Typically, the N-type dopant will be phosphorous, arsenic, or both phosporous and arsenic. In one embodiment, the dopant is phosphorous. In another, the dopant is arsenic. In yet another embodiment, phosphorous and arsenic are both used as dopants.

One advantage to using epitaxial deposition is that existing epitaxial growth reactors can be used in conjunction with a direct dopant feed during epitaxial growth. That is, the N-type dopant can be mixed with the carrier gas to dope the deposited epitaxial layer.

### VI. Post-Epi Cooling

In one embodiment, the epitaxial layer is formed in conjunction with the annealing step detailed above. In this embodiment, the epitaxial layer is formed such that the duration of the anneal step is satisfied. Upon completing the anneal and epitaxial formation, the cooling atmosphere, cooling rate, or both the cooling atmosphere and rate are controlled as detailed above. That is, in one variation of this embodiment, the atmosphere after the anneal and epitaxial layer formation is an oxygen-containing atmosphere that is capable of oxidizing an exposed silicon surface. Specifically, the atmosphere will preferably contain a partial pressure of oxygen of at least about 0.001 atmospheres (atm), or 1,000 parts per million atomic (ppma). More preferably, the partial pressure of oxygen in the atmosphere will be at least about 0.002 atm (2,000 ppma), still more preferably 0.005 atm (5,000 ppma), and still more preferably 0.01 atm (10,000 ppma).

In other variations of this embodiment, the cooling rate of the wafer is controlled with or without controlling the cooling atmosphere. Specifically, the cooling rate is controlled such that the average cooling rate from the annealing temperature to the temperature at which vacancies are practically immobile (e.g., about 950° C.) is preferably no more than 20° C. per second, more preferably no more than about 10° C. per second, and still more preferably no more than about 5° C. per second. Alternatively, the temperature may be reduced quickly (e.g., at a rate greater than about 20° C./second) to a temperature of less than about 1150° C. but greater than about 950° C., and then held for a time period between several seconds to several minutes, depending upon the holding temperature. For example, at least about 2, 3, 4, 6 seconds or more may be sufficient for temperatures near 1150° C., whereas at least about 2, 3, 4, 6 minutes or more may be required for temperatures near 950° C.

### VII. Polysilicon Layer

In one embodiment, a polysilicon layer is deposited on the backside of the highly doped substrate prior to the annealing step described above. The grain boundaries of the polysilicon layer serve as a gettering site for dopant. In general, the polysilicon layer may be deposited by any means conventionally known in the art. For example, the polysilicon layer may be deposited by chemical vapor deposition using silane (SiH₄) gas and arsenic doping, as more fully described in U.S. Pat. No. 5,792,700 or 5,310,698.

Silicon structures manufactured according to this invention may be used in various technologies. For example, the silicon structure of this invention is suitable for use in the manufacture of power devices, such as power diodes, thyristors, and, in particular, power MOSFETs and JFETs. This list is in no way intended to be restrictive or comprehensive.

When introducing elements of the present invention or the preferred embodiments(s) thereof, the articles “a”, “an”, “the”, and “said” are intended to mean that there are one or more of the elements. The terms “comprising”, “including”, and “having” are intended to be inclusive and mean that there may be additional elements other than the listed elements. Moreover, unless explicitly noted otherwise, reference to the heavily doped substrate as “N+” or “P+” should be understood to also refer to substrates having doping levels conventionally referred to as N++ and N+++ or P++ and P+++, respectively.

In view of the above, it will be seen that the several objects of the invention are achieved and other advantageous results attained.

As various changes could be made in the above products and methods without departing from the scope of the invention, it is intended that all matter contained in the above description and shown in the accompanying drawings shall be interpreted as illustrative and not in a limiting sense.

What is claimed is:

1. A process for preparing an epitaxial single crystal silicon wafer, the process comprising:
annealing a heavily doped single crystal silicon substrate at a temperature of at least 1150° C. to dissolve pre-existing oxygen precipitates, the heavily doped silicon substrate being the slice of an ingot grown by the Czochralski method having a front surface, a back surface, and a circumferential edge joining the front and back surfaces, and having a resistivity of less than 5 mΩ*cm;
depositing an N− silicon epitaxial layer on the front surface of the rapidly heated heavily doped silicon substrate to form the epitaxial silicon wafer, the epitaxial layer comprising an N-type dopant and having a resistivity of greater than about 10 mΩ*cm; and
cooling the heavily doped silicon substrate from the annealing temperature to room temperature, wherein (i) the atmosphere of the annealing step is controlled or (ii) the cooling rate is controlled during the cooling step to install a uniform concentration of vacancies in the heavily doped single crystal silicon substrate, the uniform concentration being insufficient to catalyze oxygen precipitation in an oxidation precipitation heat-treatment.

2. The process of claim 1 wherein the cooling step is carried out before the depositing step.

3. The process of claim 2 wherein the atmosphere in which the annealing step is carried out comprises oxygen.

4. The process of claim 3 wherein the atmosphere comprises a partial pressure of oxygen of at least about 1000 ppma.

5. The process of claim 2 wherein the cooling rate is no more than 20° C. per second from the annealing temperature to the temperature at which vacancies are practically immobile.

6. The process of claim 2 wherein the cooling rate is no more than 5° C. per second from the annealing temperature to the temperature at which vacancies are practically immobile.

7. The process of claim 1 wherein the annealing step and the depositing step are carried out in the same apparatus, the cooling step is carried out after the depositing step, and the cooling rate is no more than 20° C. per second from the annealing temperature to the temperature at which vacancies are practically immobile.

8. The process of claim 1 wherein the annealing step and the depositing step are carried out in the same apparatus, the cooling step is carried out after the depositing step, and the cooling rate is no more than 5° C. per second from the annealing temperature to the temperature at which vacancies are practically immobile.

9. The process of claim 2 wherein cooling the heavily doped silicon substrate comprises cooling at a cooling rate greater than 20° C. per second from the annealing temperature to a temperature of less than about 1150° C. but greater than about 950° C., and then holding the substrate within this temperature range for at least about 2 seconds.

10. The process of claim 9 wherein the heavily doped silicon substrate is cooled to a temperature of about 950° C., at which it is held for at least about 2 minutes.

11. The process of claim 1 wherein the heavily doped silicon substrate comprises an N-type dopant.

12. The process of claim 11 wherein the heavily doped silicon substrate comprises a dopant selected from the group consisting of P, As, and combinations thereof.

13. The process of claim 1 wherein the heavily doped silicon substrate comprises a P-type dopant.

14. The process of claim 13 wherein the heavily doped silicon substrate comprises a dopant selected from the group consisting of B, Al, Ga, and combinations thereof.

15. The process of claim 1 wherein the N− silicon epitaxial layer is deposited to a thickness of at least about 5 cm.

16. The process of claim 1 further comprising depositing a layer of polysilicon on the back surface of the heavily doped single crystal silicon substrate before the annealing step.

17. An epitaxial silicon wafer comprising:
a heavily doped single crystal silicon substrate that is a slice of an ingot grown by the Czochralski method having a front surface, a back surface, and a circumferential edge joining the front and back surfaces; having a resistivity of less than 5 mΩ*cm; and being substantially free of oxygen precipitate nuclei;
an N− silicon epitaxial layer on the front surface of the heavily doped silicon substrate forming the epitaxial silicon wafer, the epitaxial layer comprising an N-type dopant and having a resistivity of greater than about 10 mΩ*cm.

18. The wafer of claim 17 wherein the heavily doped silicon substrate comprises an N-type dopant.

19. The wafer of claim 18 wherein the heavily doped silicon substrate comprises a dopant selected from the group consisting of P, As, and combinations thereof.

20. The wafer of claim 17 wherein the heavily doped silicon substrate comprises a P-type dopant.

21. The wafer of claim 20 wherein the heavily doped silicon substrate comprises a dopant selected from the group consisting of B, Al, Ga, and combinations thereof.

22. The wafer of claim 17 wherein the N− silicon epitaxial layer has a thickness of at least about 5 cm.

23. The wafer of claim 17 wherein the epitaxial layer has a resistivity of between about 100 mΩ·cm and about 100 Ω·cm.

24. The wafer of claim 17 wherein the heavily doped silicon substrate comprises a region having a substantially uniform concentration of oxygen interstitial atoms that extends radially from the center of the wafer to a distance that is within 15 microns of the surface of the wafer.

25. The wafer of claim 24 wherein the substantially uniform region has a concentration of oxygen interstitial atoms with a variance of no more than about 50%.

26. The wafer of claim 24 wherein the substantially uniform region has a concentration of oxygen interstitial atoms with a variance of no more than about 10%.
